(19) United States
(12) Patent Application Publication
(10) Pub. No.: US 2014/0153186 A1
(43) Pub. Date: Jun. 5, 2014

(54) RACK-MOUNT SERVER ASSEMBLY WITH CABLE MANAGEMENT APPARATUS

(71) Applicants: Hong Fu Jin Precision Industry (ShenZhen) Co., Ltd., (US); Hon Hai Precision Industry Co., Ltd., (US)

(72) Inventors: MING-YU LIU, Shenzhen (CN); AN-GANG LIANG, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/717,718

(22) Filed: Dec. 18, 2012

(30) Foreign Application Priority Data
Dec. 5, 2012 (CN) 201210515031.1

(51) Int. Cl. H05K 7/18; G06F 1/16

(52) U.S. Cl. CPC H05K 7/18; G06F 1/16
USPC 361/679.58; 211/26.2

(57) ABSTRACT

A rack-mount server assembly includes a rack, a number of server modules received in the rack, and a cable management apparatus. The cable management apparatus includes a bracket attached to a rear end of the rack, a number of cable binding members for binding cables, and a number of cable positioning members for positioning the cables. The bracket includes an installing plate mounted to the rack, a front side plate extending from a front side of the installing plate, and a latching plate extending rearward from the front side plate. The installing plate, the front side plate, and the latching plate cooperatively bound a receiving slot for receiving the cables. The cable securing members are attached to the installing plate. The cable positioning members are mounted to the latching plate, and are arrayed in a row along a lengthwise direction of the latching plate.

### BACKGROUND

1. Technical Field

The present disclosure relates to a rack-mount server assembly.

2. Description of Related Art

Conventionally, a rack-mount server assembly includes a rack, a plurality of server modules received in the rack, and a switch generally mounted on a top of the rack. Many cables are needed in the rack for transferring signals or providing power. However, the cables are not arranged orderly.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an exemplary embodiment of a rack-mount server assembly, wherein the rack-mount server assembly includes a cable management apparatus including a plurality of cable positioning members.

FIG. 2 is an enlarged view of the circled portion II of FIG. 1.

FIG. 3 is an enlarged view of one of the cable positioning members of FIG. 1, but viewed from another perspective.

FIG. 4 is an assembled, isometric view of the rack-mount server assembly of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

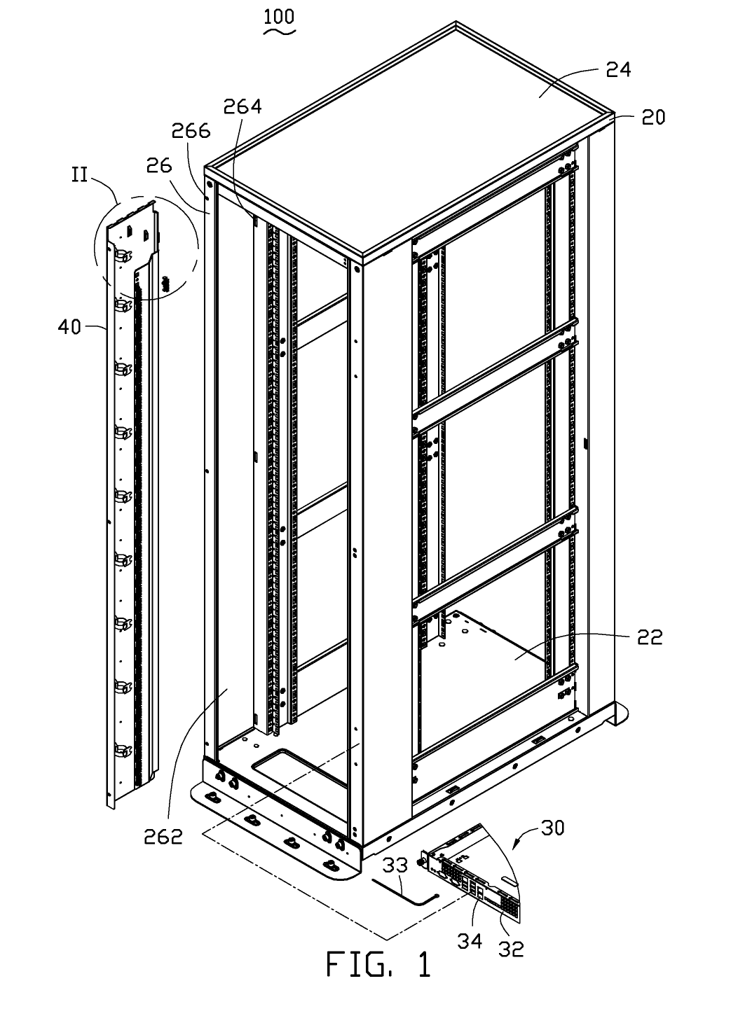

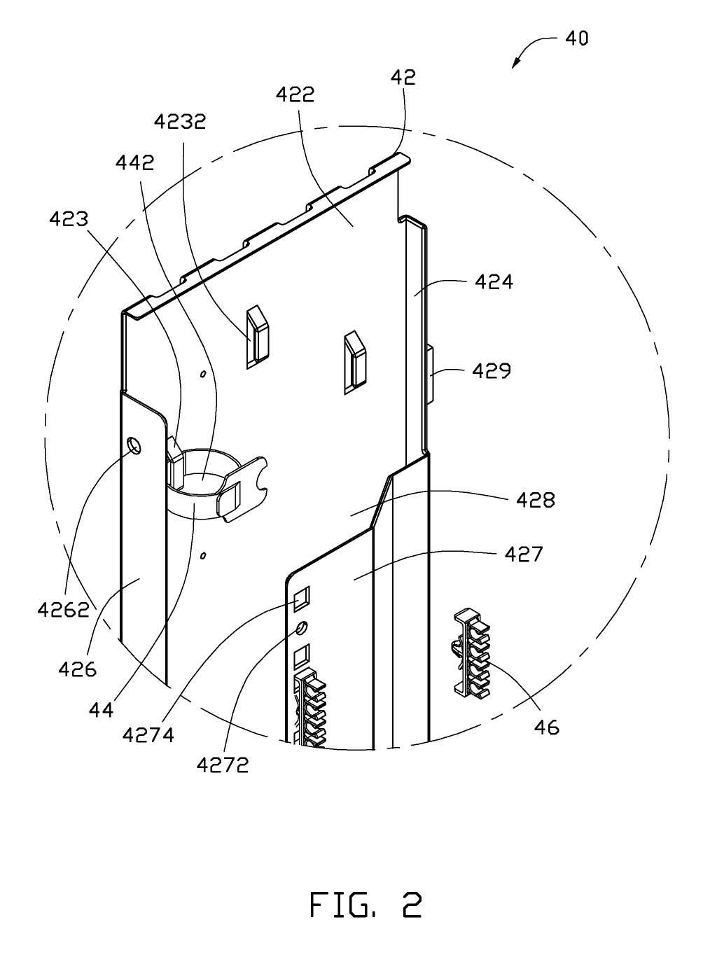

FIG. 1 and FIG. 2 show an exemplary embodiment of a rack-mount server assembly 100. The rack-mount server assembly 100 includes a rack 20, a plurality of server modules 30 received in the rack 20, and a cable management apparatus 40.

The rack 20 includes a rectangular base 22, a top wall 24 opposite to the base 22, and four support poles 26 respectively connected between four corners of the base 22 and the top wall 24. One of the support poles 26 located at a rear end of the rack 20 defines a receiving space 262 in an inner surface of the support pole 26. A front side of the support pole 26 defines a plurality of latching holes 264 communicating with the receiving space 262, and a rear side of the support pole 26 defines a plurality of through holes 266 communicating with the receiving space 262.

The server modules 30 can be inserted into the rack 20. Each server module 30 includes a rear wall 32 defining a plurality of ports 34 for receiving ends of cables 33.

The cable management apparatus 40 includes a bracket 42, a plurality of cable binding members 44, and a plurality of cable positioning members 46.

The bracket 42 includes a rectangular installing plate 422, a front side plate 424 and a rear side plate 426 perpendicularly extending from two opposite sides of the installing plate 422 toward the same direction, and a latching plate 427 extending from the front side plate 424 toward the rear side plate 426. The installing plate 422, the front side plate 424, and the latching plate 427 cooperatively bound a receiving slot 428. A plurality of protrusions 429 protrudes out from the front side plate 424, opposite to the latching plate 427. The rear side plate 426 defines a plurality of screw holes 4262. The latching plate 427 defines a plurality of spaced latching holes 4272 away from the front side plate 424, and the lathing holes 4272 are arrayed in a row along a lengthwise direction of the rear side plate 426. The latching plate 427 defines two positioning holes 4274 located at top side and bottom side of each latching hole 4272.

A plurality of retaining portions 423 protrudes from the installing plate 422 adjacent to the rear side plate 426 toward the latching plate 427. The retaining portions 423 are arrayed in a row along the lengthwise direction of the rear side plate 426. In an embodiment, each retaining portion 423 is bridge-shaped. A gap 4232 is defined between each retaining portion 423 and an inner surface of the installing plate 422. Each retaining portion 423 is capable of hanging one cable binding member 44. Each cable binding member 44 is strip-shaped, and can bound a holding hole 442.

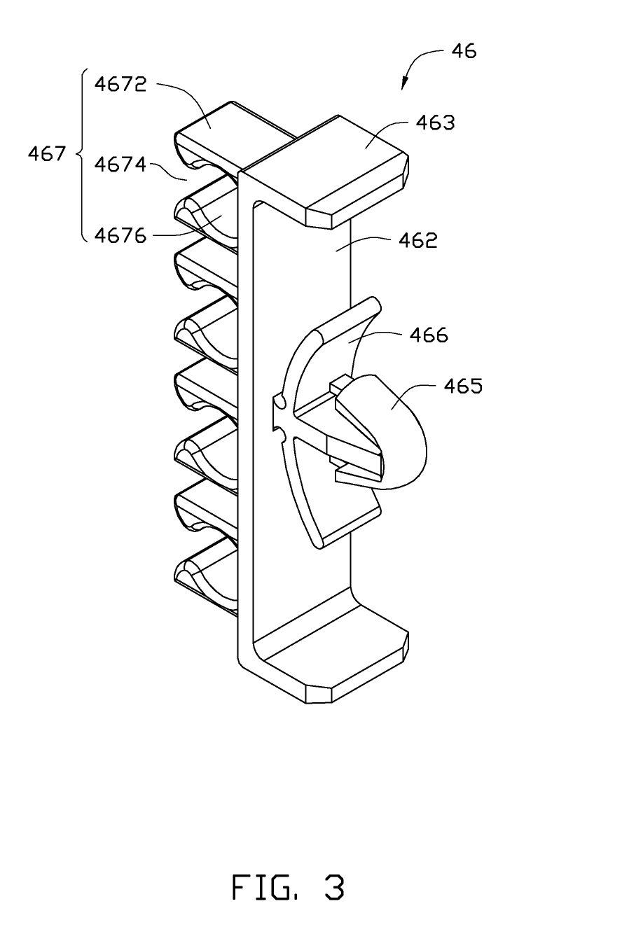

FIG. 3 shows one of the cable positioning members 46. The cable positioning member 46 includes a bar-shaped connecting plate 462, two opposite positioning pieces 463 extending from two ends of the connecting plate 462 toward the same direction, a hook 465 protruding from a middle of the connecting plate 462 along the extending direction of the positioning pieces 463, and a plurality of latching portions 467 protruding from the connecting plate 462 away from the positioning pieces 463. The latching portions 467 are arrayed in a row along the lengthwise direction of the connecting plate 462. Two arc-shaped and resilient abutting pieces 466 respectively extend out from two opposite sides of the hook 465. Each abutting piece 466 is located between the corresponding positioning piece 463 and the hook 465. Each latching portion 467 includes two opposite resilient clamping pieces 4672. The clamping pieces 4672 of each latching portion 467 cooperatively bound a clamping slot 4676 defining an opening 4674 opposite to the connecting plate 462.

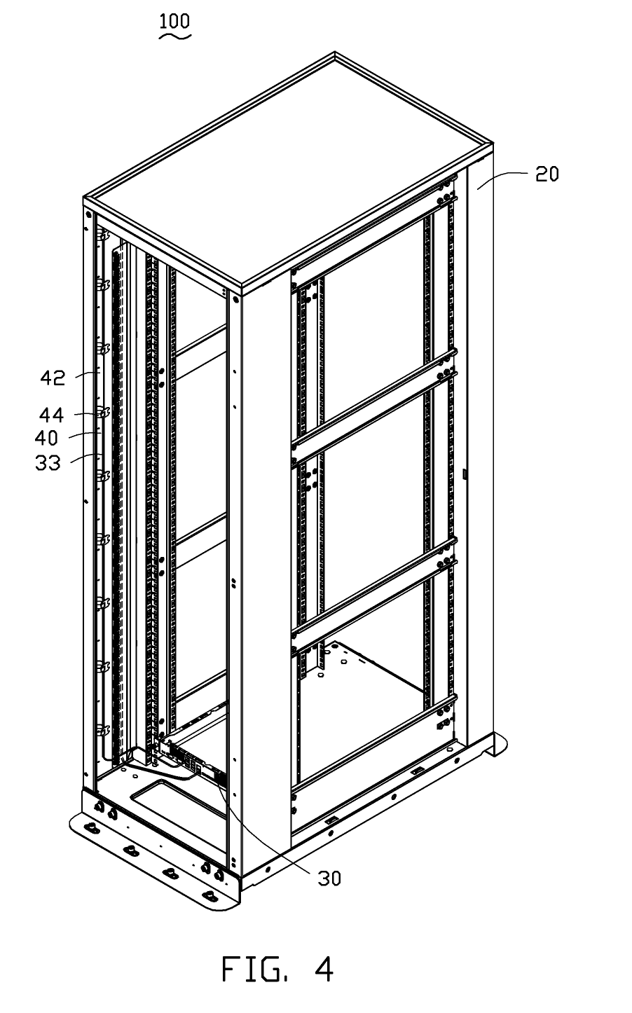

FIG. 4 shows that in assembly, the hook 465 of each cable positioning member 46 is inserted into the corresponding latching hole 4272 of the bracket 42, to allow the positioning pieces 463 to be inserted into the corresponding positioning holes 4274, and the abutting pieces 466 are resiliently abutted against the latching plate 427. The bracket 42 is received in the receiving space 262 of the support pole 26. The protrusions 429 are respectively inserted into the latching holes 264. A plurality of screws extends through the through holes 266 of the support pole 26, to be screwed into the screw holes 4262, respectively.

In use, the server modules 30 are installed in the rack 20. The rear wall 32 is adjacent to the bracket 42. First ends of the cables 33 are engaged in the ports 34 of the server modules 30, some of the cables 33 are then received in the receiving slot 428 of the bracket 42, and the other cables 33 are respectively clamped in the clamping slots 4676 through the corresponding opening 4674 and then are bound by the corresponding cable binding members 44. Therefore, the cables 33 can be arranged in a well-ordered manner.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A cable management apparatus to manage cables of a rack-mount server, the rack-mount server comprising a support pole defining a receiving space in an inner surface of the support pole, the cable management apparatus comprising:
a bracket received in the receiving space, and comprising an installing plate, a front side plate extending out from a front side of the installing plate, and a latching plate extending rearward from the front side plate;
a plurality of cable positioning members mounted to the latching plate and arrayed in a row along a lengthwise direction of the latching plate for positioning a first part of the cables;
a plurality of cable binding members attached to the installing plate for binding the first part of cables; and
wherein the installing plate, the front side plate, and the latching plate cooperatively bound a receiving slot for receiving a second part of the cables.

2. The cable management apparatus of claim 1, wherein the installing plate is rectangular, a plurality of retaining portions protrudes from the installing plate and is arrayed in a row along the lengthwise direction of the installing plate, the cable binding members are respectively hung the retaining portions.

3. The cable management apparatus of claim 2, wherein the latching plate defines a plurality of latching holes arrayed in a row along the lengthwise direction of the latching plate, each cable positioning member comprises a bar-shaped connecting plate, a hook protruding from the connecting plate and inserted into the corresponding latching hole, and a plurality of latching portions protruding from the connecting plate away from the hook for positioning the corresponding cables.

4. The cable management apparatus of claim 3, wherein the latching plate defines two opposite positioning holes located at top and bottom sides of each latching hole respectively, each cable positioning member further comprises two positioning pieces extending from two ends of the connecting plate respectively latched into the positioning holes.

5. The cable management apparatus of claim 3, wherein each latching portion comprises two opposite resilient clamping pieces, the clamping pieces cooperatively bound a clamping slot for receiving the corresponding cable.

6. The cable management apparatus of claim 3, wherein two resilient abutting pieces respectively extending out from two opposite sides of each hook, the abutting pieces are resiliently abutted against the latching plate.

7. A cable management apparatus to manage cables of a rack-mount server, the rack-mount server comprising a support pole defining a receiving space in an inner surface of the support pole, the cable management apparatus comprising:
a bracket received in the receiving space, and comprising an installing plate, a front side plate extending out from a front side of the installing plate, and a latching plate extending rearward from the front side plate; and
a plurality of cable positioning members mounted to the latching plate and arrayed on an outer surface of the latching plate in a row along a lengthwise direction of the latching plate;
wherein, in managing the cables, the cables are respectively clamped in the cable positioning members.

8. The cable management apparatus of claim 7, wherein the latching plate defines a plurality of latching holes arrayed in a row along the lengthwise direction of the latching plate, each cable positioning member comprises a bar-shaped connecting plate, a hook protruding from the connecting plate and inserted into the corresponding latching hole, and a plurality of latching portions protruding from the connecting plate away from the hook for positioning the corresponding cables.

9. The cable management apparatus of claim 8, wherein the latching plate defines two opposite positioning holes located at top and bottom sides of each latching hole respectively, each cable positioning member further comprises two positioning pieces extending from two ends of the connecting plate respectively latched into the positioning holes.

10. The cable management apparatus of claim 8, wherein each latching portion comprises two opposite resilient clamping pieces, the clamping pieces cooperatively bound a clamping slot for receiving the corresponding cable.

11. The cable management apparatus of claim 8, wherein two resilient abutting pieces respectively extending out from two opposite sides of each hook, the abutting pieces are resiliently abutted against the latching plate.

12. A rack-mount server assembly, comprising:
a rack;
a plurality of server modules received in the rack; and
a cable management apparatus comprising a bracket attached to a rear end of the rack, a plurality of cable binding members mounted to the bracket for arranging cables, and a plurality of cable positioning members for positioning the cables;
wherein the bracket comprises an installing plate mounted to the rack, a front side plate extending inner from a front side of the installing plate, and a latching plate extending rearward from the front side plate, the installing plate, the front side plate, and the latching plate cooperatively bound a receiving slot for receiving the cables, the cable binding members are attached to the installing plate, the cable positioning members are mounted to the latching plate, and are arrayed in a row along a lengthwise direction of the latching plate.

13. The rack-mount server assembly of claim 12, wherein the rack comprises a base, a top wall opposite to the base, and four support poles respectively connected between four corners of the base and the top wall, one of the support poles located on the rear end of the rack defines a receiving space for receiving the bracket.

14. The rack-mount server assembly of claim 13, wherein the installing plate is rectangular, a plurality of retaining portions protrudes from the installing plate and is arrayed in a row along the lengthwise direction of the installing plate, the cable binding members are respectively hung to the retaining portions.

15. The rack-mount server assembly of claim 13, wherein the latching plate defines a plurality of latching holes arrayed in a row along the lengthwise direction of the latching plate, each cable positioning member comprises a bar-shaped connecting plate, a hook protruding from a side of the connecting plate and inserted into the corresponding latching hole, and a plurality of latching portion protruding from the connecting plate away from the hook for positioning the cables.

16. The rack-mount server assembly of claim 15, wherein the latching plate defines two opposite positioning holes located at top and bottom sides of each latching hole respectively, each cable positioning member further comprises two positioning pieces extending from two ends of the connecting plate and respectively latched into the positioning holes.

17. The rack-mount server assembly of claim 15, wherein each latching portion comprises two opposite resilient clamping pieces, the clamping pieces cooperatively bound a clamping slot for receiving the corresponding cable.

18. The rack-mount server assembly of claim 15, wherein two resilient abutting pieces respectively extending out from two opposite sides of each hook, the abutting pieces are resiliently abutted against the latching plate.
